(19) United States
(12) Patent Application Publication
(10) Pub. No.: US 2017/0352574 A1
(43) Pub. Date: Dec. 7, 2017

(54) APPARATUS AND METHOD FOR TREATING WAFER

(71) Applicant: TAIWAN SEMICONDUCTOR MANUFACTURING CO., LTD., Hsinchu (TW)

(72) Inventors: Kei-Wei CHEN, Tainan City (TW); Chun-Hsiung TSAI, Hsinchu County (TW); Huai-Tei YANG, Hsinchu City (TW); Shiu-Ko JANGJIAN, Tainan City (TW); Ying-Lang WANG, Taichung City (TW); Ziwei FANG, Hsinchu County (TW)

(73) Assignee: TAIWAN SEMICONDUCTOR MANUFACTURING CO., LTD., HSINCHU (TW)

(21) Appl. No.: 15/171,806

(22) Filed: Jun. 2, 2016

(51) Int. Cl. H01L 21/687; H01L 21/3065; H01J 37/32; H01L 21/67

(52) U.S. Cl. CPC H01L 21/68764; H01L 21/67069; H01L 21/30655; H01J 37/32082; H01J 37/3244; H01J 2237/334

(57) ABSTRACT

An apparatus for treating a wafer is provided. The apparatus includes a platen, a chamber, an etch gas supplier and a tilting mechanism. The chamber has at least one aperture at least partially facing to the platen. The etch gas supplier is fluidly connected to the chamber. The tilting mechanism is coupled with the platen for allowing the platen to have at least one first degree of freedom to tilt relative to the aperture of the chamber.

### BACKGROUND

Atomic layer etching (ALE) is an etching technique in semiconductor manufacture. ALE uses a sequence alternating between self-limiting chemical modification steps which affect the top atomic layers of the wafer, and etching steps which remove the chemically-modified areas, to allow the removal of individual atomic layers.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of an apparatus in accordance with some embodiments of the present disclosure.

FIG. 2 is an enlarged sectional view of a portion of the wafer of FIG. 1.

FIG. 3 is a schematic view of an apparatus in accordance with some other embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

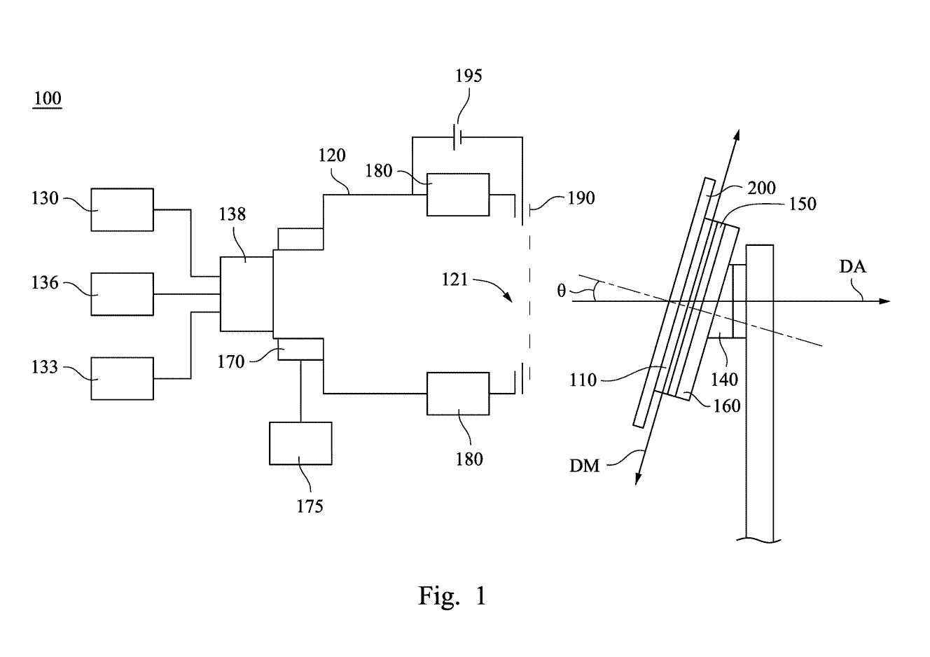

Reference is made to FIG. 1. FIG. 1 is a schematic view of an apparatus 100 in accordance with some embodiments of the present disclosure. As shown in FIG. 1, the apparatus 100 for treating a wafer 200 is provided. The apparatus 100 includes a platen 110, a chamber 120, an etch gas supplier 130, and a tilting mechanism 140. The chamber 120 has at least one aperture 121. The aperture 121 at least partially faces to the platen 110. The platen 110 is configured to hold the wafer 200, such that the wafer 200 at least partially faces to the aperture 121 of the chamber 120. The etch gas supplier 130 is fluidly connected to the chamber 120. The tilting mechanism 140 is coupled with the platen 110 for allowing the platen 110 to have at least one first degree of freedom to tilt relative to the aperture 121 of the chamber 120.

In other words, the angle of the platen 110 relative to the aperture 121 of the chamber 120 is able to be adjusted by the tilting mechanism 140. As shown in FIG. 1, the direction DA of the aperture 121 pointing towards the platen 110 forms an angle θ with the direction of the normal of the platen 110. Since the wafer 200 is held by the platen 100, the angle of the normal of the wafer 200 relative to the direction DA of the aperture 121 pointing towards the platen 110 is able to be adjusted by the tilting mechanism 140. For example, in some embodiments, the wafer 200 is tilted by the angle θ relative to the direction DA of the aperture 121 pointing towards the platen 110. In practical applications, the angle θ can be positive or negative.

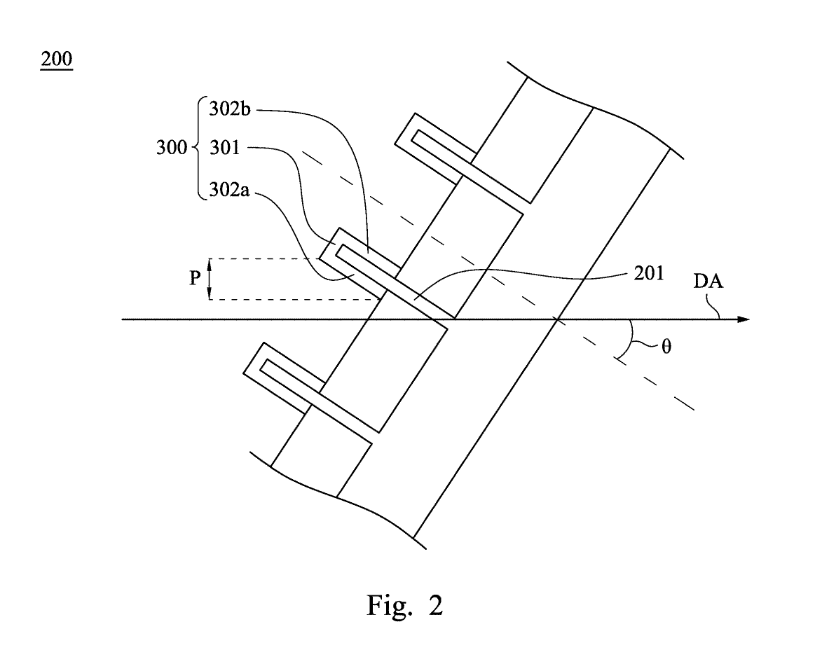

FIG. 2 is an enlarged sectional view of a portion of the wafer 200 of FIG. 1. As shown in FIGS. 1 and 2, the direction DA of the aperture 121 pointing towards the platen 110 forms the angle θ with the direction of the normal of the wafer 200. Moreover, the material 300 on the surface of the wafer 200 includes a surface portion 301 and side portions 302a and 302b. The surface portion 301 connects the side portions 302a and 302b. The surface portion 301 is substantially perpendicular to the normal of the wafer 200, while the side portions 302a and 302b are substantially parallel with the normal of the wafer 200. Practically, the surface portion 301 and the side portions 302a and 302b at least partially cover a protruding portion 201 of the wafer 200, such as a semiconductor fin.

During the operation of the apparatus 100, the etch gas supplier 130 supplies an etch gas into the chamber 110. For instance, the etch gas can be an inert gas, such as argon or neon. The etch gas is ionized in the chamber 110. Then, the ionized etch gas is directed through the aperture 121 of the chamber 110 and reaches the material 300 on the surface of the wafer 200. The material 300 can be removed by bombardment with the ionized etch gas.

As mentioned above, the material 300 includes the surface portion 301 and the side portions 302a and 302b. Since the wafer 200 is tilted by the angle θ relative to the direction DA of the aperture 121 pointing towards the platen 110, both the surface portion 301 and the side portion 302a can be reached by the ionized etch gas. This means removal of both the surface portion 301 and the side portion 302a can be carried out accordingly. In this way, etching of the material 300 on the wafer 200 can be carried out by the apparatus 100 in a three-dimensional manner.

To be more specific, the side portion 302a forms a projected area P towards the aperture 121 of the chamber 120. The size of the projected area P is related to the magnitude of the angle θ. In other words, the more the platen 110 is tilted by the tilting mechanism 140, the larger the size of the projected area P of the side portion 302a will be. With a larger projected area P of the side portion 302a towards the aperture 121 of the chamber 120, the side portion 302a is exposed to the ionized etch gas more readily, and the effectiveness of the etching of the side portion 302a of the material 300 by the ionized etch gas is correspondingly increased.

In addition, as shown in FIGS. 1 and 2, the apparatus 100 further includes a rotating mechanism 150. The rotating mechanism 150 is coupled with the platen 110 for allowing the platen 110 to have at least one second degree of freedom to rotate relative to the aperture 121 of the chamber 120 either clockwise or anti-clockwise. To be more specific, during the operation of the apparatus 100, the platen 110 is rotated about the normal of the platen 110 by the rotating mechanism 150. In this way, the side portions 302a and 302b of the material 300 covering around the protruding portion 201 of the wafer 200 can be exposed to the ionized etch gas alternately. For instance, when the side portion 302a is at least partially exposed to the ionized etch gas, the side portion 302b on the other side of the protruding portion 201 is blocked from the ionized etch gas by the protruding portion 201. However, after the platen 110 and thus the wafer 200 is rotated by the rotating mechanism 150 either clockwise or anti-clockwise, the side portion 302b on the other side of the protruding portion 201 will be turned and exposed to the ionized etch gas instead. As a result, etching of the side portion 302b can be carried out. Therefore, the side portions 302a and 302b of the material 300 covering around the protruding portion 201 of the wafer 200 can be exposed to the ionized etch gas alternately under the action of the rotating mechanism 150.

In order to ionize the etch gas, the apparatus 100 includes at least one radio frequency generator 170. As shown in FIG. 1, the radio frequency generator 170 is disposed at an end of the chamber 120 away from the aperture 121 and is coupled with the chamber 120. In practical applications, the radio frequency generator 170 includes a radio frequency coil. When the etch gas supplier 130 supplies the etch gas into the chamber 110, the radio frequency generator 170 operates to energize the etch gas. In this way, the etch gas is energized to form a plasma. The plasma is in fact a mixture of the etch gas ions and electrons. The etch gas in the form of plasma can remove the material 300 on the wafer 200 more readily. In some embodiments, the plasma can be inductively coupled plasma (ICP). In some other embodiments, the plasma can be capacitively coupled plasma (CCP).

In addition, the apparatus 100 further includes at least a pair of magnets 180 with opposite poles. The pair of magnets 180 is coupled with the chamber 120. As shown in FIG. 1, the aperture 121 is substantially located between the pair of magnets 180. The pair of magnets 180 generates a magnetic field over the aperture 121 of the chamber 120. After the etch gas is energized to become the form of plasma by the radio frequency generator 170 as mentioned above, the etch gas in the form of plasma is influenced by the magnetic field when the plasma is directed towards the aperture 121 of the chamber 120. Since the plasma is in fact a mixture of the etch gas ions and electrons, at least the electrically charged ions will be affected by the magnetic field and become effectively diverse. Afterwards, the etch gas ions will be directed to the material 300 on the wafer 200 as an ion beam.

In some embodiments, as shown in FIG. 1, the apparatus 100 further includes at least one grid 190 and a power supply 195. In practical applications, the grid 190 at least partially covers the aperture 121 of the chamber 120. The power supply 195 is configured to bias the grid 190 relative to the chamber 120. During the operation of the apparatus 100, the power supply 195 is turned on and thus the grid 190 becomes negatively charged while the chamber 120 positively charged. As a result, the positively charged ion beam of the etch gas will be accelerated towards the negatively charged grid 190. Thus, the ion beam will be directed to bombard on the material 300 on the wafer 200 and remove the material 300 accordingly.

In some embodiments, the grid 190 may detachably cover the aperture 121 of the chamber 120. In other words, in practical applications, when the grid 190 is detached optionally, the aperture 121 of the chamber 120 is fully opened.

In some embodiments, as shown in FIG. 1, the apparatus 100 further includes at least one linear motion mechanism 160. In practice, the linear motion mechanism 160 is coupled with the platen 110 for allowing the platen 110 to have at least one third degree of freedom to move relative to the aperture 121 of the chamber 120. To be more specific, the linear motion mechanism 160 is connected between the tilting mechanism 140 and the platen 110. As shown in FIG. 1, the platen 110 is able to be moved linearly along at least a movement direction DM. In some embodiments, the movement direction DM is substantially perpendicular to the direction of the normal of the platen 110. In this way, the wafer 200 held by the platen 110 can be moved linearly along the movement direction DM such that different portions of the wafer 200 can be exposed correspondingly to the aperture 121 of the chamber 120.

On the other hand, the apparatus 100 further includes a reactive gas supplier 133 and a gas switch 138. As shown in FIG. 1, the gas switch 138 fluidly connects the etch gas supplier 130, the reactive gas supplier 133 and the chamber 120. In practical applications, the reactive gas supplier 133 supplies a reactive gas into the chamber 110. For instance, the reactive gas can be, for example, chlorine or fluorine. The reactive gas is then directed through the aperture 121 of the chamber 110 and reaches the wafer 200 to form, for example, an etch layer on the material 300. The gas switch 138 is switchable between the fluid connection of the reactive gas supplier 133 with the chamber 120 and the fluid connection of the etch gas supplier 130 with the chamber 120. In other words, when the reactive gas supplier 133 is fluidly connected with the chamber 120, the etch gas supplier 130 and the chamber 120 will not be fluidly connected then. On the contrary, when the etch gas supplier 130 is fluidly connected with the chamber 120, the reactive gas supplier 133 and the chamber 120 will not be fluidly connected then. As a result, formation of the etch layer and removal of the etch layer by the ionized etch gas can be carried out alternatively. That is, the apparatus 100 may perform atomic layer etching (ALE) or quasi-ALE on the material 300, and the apparatus 100 may be, for example, an ALE or quasi-ALE tool.

To facilitate the operation of the apparatus 100, in some embodiments, the apparatus 100 further includes a controller 175. The controller 175 is configured to turn on the radio frequency generator 170 when the gas switch 138 is switched to fluidly connect the etch gas supplier 130 to the chamber 120 and turn off the radio frequency generator 170 when the gas switch 138 is switched to the fluid connection of the reactive gas supplier 133 with the chamber 120. In this way, the radio frequency generator 170 functions when the etch gas supplier 130 is supplying the etch gas into the chamber 120 and is disabled when the reactive gas supplier 133 is supplying the reactive gas into the chamber 120, making sure the proper operation of the apparatus 100.

In a nutshell, the operation of the apparatus 100 comes as a repeated cycle with a sequence with at least the operations including the formation of the etch layer and the removal of the etch layer by the ionized etch gas. The formation of the etch layer may be performed in a temperature ranging from about 150 to about 400 degree Celsius and in a pressure ranging from about 0.1 to about 100 mT. The radio frequency generator 170 is turned off during the formation of the etch layer. The power supply 195 is turned off during the formation of the etch layer. The linear motion mechanism 160 is set static and the angle θ of the wafer 200 being tilted relative to the direction DA of the aperture 121 pointing towards the platen 110 is set to be substantially zero during the formation of the etch layer.

After the formation of the etch layer is completed, the removal of the etch layer by the ionized etch gas will then be in progress. The removal of the etch layer may be performed in a temperature ranging from about 50 to about 200 degree Celsius and in a pressure ranging from about 1 to about 100 mT. The radio frequency generator 170 is turned on to energize the etch gas during the removal of the etch layer. The power supply 195 is turned on such that the grid 190 is electrically charged during the removal of the etch layer. Meanwhile, both the linear motion mechanism 160 and the tilting mechanism 140 are set activated during the removal of the etch layer.

In addition, the apparatus 100 further includes a cleaning gas supplier 136. Similarly, the gas switch 138 fluidly connects the etch gas supplier 130, the reactive gas supplier 133, the cleaning gas supplier 136 and the chamber 120. In practical applications, the cleaning gas supplier 136 supplies a cleaning gas into the chamber 110 in order to perform an in-situ cleaning process after the atomic layer etching. For instance, the cleaning gas can be, for example, nitrogen trifluoride (NF3) or tetrafluoromethane (CF4). To be more specific, the gas switch 138 is switchable between the fluid connection of the reactive gas supplier 133 with the chamber 120, the fluid connection of the etch gas supplier 130 with the chamber 120, and the fluid connection of the cleaning gas supplier 136 with the chamber 120. In other words, when the reactive gas supplier 133 is fluidly connected with the chamber 120, the etch gas supplier 130, the cleaning gas supplier 136 and the chamber 120 will not be fluidly connected then. On the contrary, when the etch gas supplier 130 is fluidly connected with the chamber 120, the reactive gas supplier 133, the cleaning gas supplier 136 and the chamber 120 will not be fluidly connected then. Eventually, when the cleaning gas supplier 136 is fluidly connected with the chamber 120, the etch gas supplier 130, the reactive gas supplier 133 and the chamber 120 will not be fluidly connected.

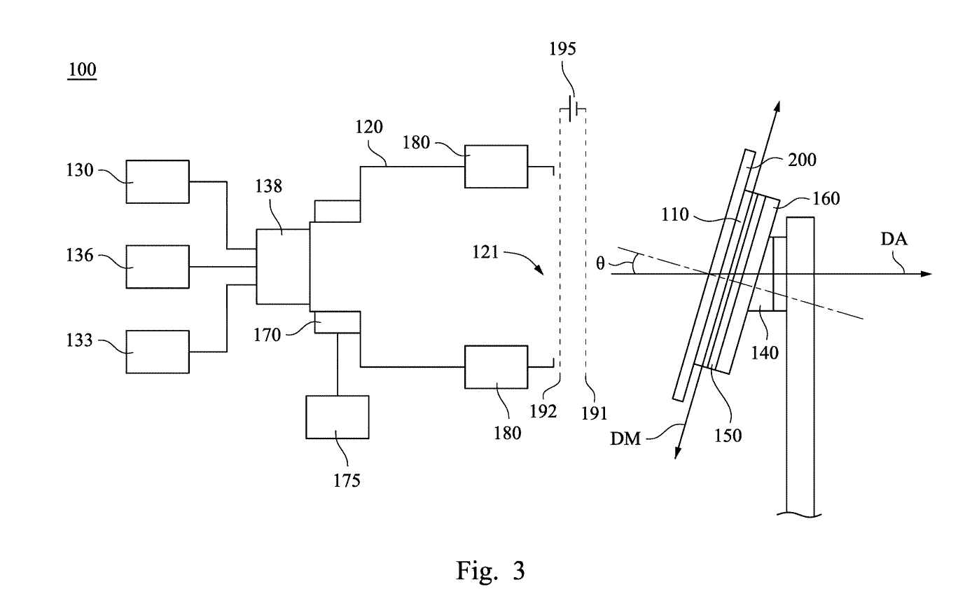

Reference is made to FIG. 3. FIG. 3 is a schematic view of an apparatus 100 in accordance with some other embodiments of the present disclosure. As shown in FIG. 3, the apparatus 100 includes at least one outer grid 191 and at least one inner grid 192. The inner grid 192 is disposed between the outer grid 191 and the chamber 120 and corresponds to the aperture 121 of the chamber 120. The inner grid 192 is substantially parallel and aligned with the outer grid 191. The power supply 195 is configured to bias the outer grid 191 relative to the inner grid 192. During the operation of the apparatus 100, the power supply 195 is turned on and thus the outer grid 191 becomes negatively charged while the inner grid 192 positively charged. As a result, the positively charged ion beam of the ionized etch gas will be accelerated towards the negatively charged outer grid 191 after the etchant precursor deposition. Thus, the ion beam will be directed to bombard on the material 300 on the wafer 200 and remove the material 300 accordingly. Furthermore, the diameter of the inner grid 192 is in a range from about 2 to about 6 cm. In this way, the ion beam of the ionized etch gas will be focused by the inner grid 192 to have an diameter ranging from about 2 to about 6 cm as well. This control of the diameter of the ion beam of the ionized etch gas ensures that the ion beam distribution through the inner grid 192 is uniform and well-focused. Thus, the influence of overlapping between the ion beams is alleviated and the etching coverage is correspondingly achieved. In other words, the chance of local non-uniformity is reduced, facilitating both the vertical and horizontal scan of the wafer 200 to optimize the removal uniformity of the material 300.

With reference to the apparatus 100 as mentioned above, some embodiments of the present disclosure further provide a method for treating the wafer 200. The method includes the following operations (it is appreciated that the sequence of the operations and the sub-operations as mentioned below, unless otherwise specified, all can be adjusted according to the actual situations, or even executed at the same time or partially at the same time):

(1) tilting the wafer 200 at the angle θ relative to the aperture 121 of the chamber 120; and

(2) performing an etching treatment on the tilted wafer 200.

To be more specific, concerning the wafer 200 disposed with the protruding portion 201, there exists at least a part of the surface of the protruding portion 201 projecting no area towards the aperture 121 of the chamber 120 before the wafer is tilted. However, after the wafer 200 is tilted at the angle θ relative to the aperture 121 of the chamber 120, the surface of the protruding portion 201 of the wafer 200 projecting no area towards the aperture 121 before the wafer 200 is tilted will be exposed towards the aperture 121. As a result, during the etching treatment, apart from the surface of the wafer 200 substantially facing the aperture 121 already before the wafer 200 is tilted, the surface of the wafer 200 projecting no area towards the aperture 121 before the wafer 200 is tilted also faces the aperture 121. Therefore, after the wafer 200 is tilted at the angle θ relative to the aperture 121 of the chamber 120, the etching treatment on the surface of the wafer 200 projecting no area towards the aperture 121 before the wafer 200 is tilted can be performed. In other words, the etching treatment on the tilted wafer 200 can be performed by the apparatus 100 in a three-dimensional manner. In practical applications, the angle θ can be positive or negative.

In order to perform the etching treatment on various portions of the wafer 200, the method for treating the wafer 200 further includes the following operation:

(3) rotating the tilted wafer 200.

In this way, after the tilted wafer 200 is rotated either clockwise or anti-clockwise, various portions of the wafer 200 are alternatively exposed towards the aperture 121 of the chamber 120. For instance, a surface of the protruding portion 201 of the tilted wafer 200 originally located at the back of the protruding portion 201 will be exposed to the aperture 121 of the chamber 120 instead after the rotation of the tilted wafer 200. As a result, the etch treatment on the tilted wafer 200 in the three-dimensional manner can be performed accordingly.

On the other hand, in order to facilitate scanning the wafer, the method for treating the wafer 200 further includes the following operation:

(4) moving the wafer 200 along at least one linear direction, i.e., the movement direction DM as mentioned above.

With the movement of the wafer 200 relative to the aperture 121 of the chamber 120, different portions of the wafer 200 can be exposed correspondingly to the aperture 121 of the chamber 120. Thus, the portion of the wafer 200 where the etching treatment is performed can be conveniently controlled.

In some embodiments, before the etching treatment, a surface of the wafer 200 is exposed to at least one reactive gas to form an etch layer on the surface of the wafer 200, and the etching treatment removes the etch layer from the surface of the wafer. Therefore, the method for treating the wafer 200 further includes the following operation:

(5) exposing a surface of the wafer to at least one reactive gas to form an etch layer on the surface of the wafer.

That is, the method for treating the wafer 200 includes performing an atomic layer etching (ALE) or quasi-ALE process on the wafer 200. Furthermore, in some embodiments, the operations of performing the etching treatment and exposing the surface of the wafer to the reactive gas are performed in the same process chamber where at least the platen 110 and the chamber 120 are contained.

According to various embodiments of the present disclosure, since the wafer can be tilted relative to the direction of the aperture pointing towards the platen by the tilting mechanism, both the surface portion and the side portion of the material on the wafer can be reached by the ionized etch gas. This means removal of both the surface portion and the side portion of the material can be carried out accordingly. In this way, atomic layer etching of the material on the wafer can be carried out by the apparatus in a three-dimensional manner.

According to various embodiments of the present disclosure, the apparatus for treating the wafer is provided. The apparatus includes the platen, the chamber, the etch gas supplier and the tilting mechanism. The chamber has the aperture at least partially facing towards the platen. The etch gas supplier is fluidly connected to the chamber. The tilting mechanism is coupled with the platen for allowing the platen to have the first degree of freedom to tilt relative to the aperture of the chamber.

According to various embodiments of the present disclosure, the apparatus for treating the wafer is provided. The apparatus includes the platen, the chamber, the etch gas supplier and the rotating mechanism. The chamber has the aperture at least partially facing towards the platen. The etch gas supplier is fluidly connected to the chamber. The rotating mechanism is coupled with the platen for allowing the platen to have at least two degree of rotational freedom.

According to various embodiments of the present disclosure, the method for treating the wafer is provided. The method includes tilting the wafer and performing the etching treatment on the tilted wafer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. An apparatus for treating a wafer, the apparatus comprising:
a platen;
a chamber having at least one aperture at least partially facing to the platen;
an etch gas supplier fluidly connected to the chamber;
a tilting mechanism coupled with the platen for allowing the platen to have at least one first degree of freedom to tilt relative to the aperture of the chamber; and
at least one linear motion mechanism coupled with the platen for allowing the platen to have at least one third degree of freedom to move linearly relative to the aperture of the chamber in a direction substantially perpendicular to a normal of the platen.

2. The apparatus of claim 1, further comprising:
a rotating mechanism coupled with the platen for allowing the platen to have at least one second degree of freedom to rotate relative to the aperture of the chamber.

3. (canceled)

4. The apparatus of claim 1, wherein the linear motion mechanism is connected between the tilting mechanism and the platen.

5. The apparatus of claim 1, further comprising:
at least one radio frequency generator coupled with the chamber.

6. The apparatus of claim 1, further comprising:
at least a pair of magnets with opposite poles coupled with the chamber, the aperture being substantially located between the pair of magnets.

7. The apparatus of claim 1, further comprising:
at least one grid at least partially covering the aperture; and
a power supply configured to bias the grid relative to the chamber.

8. The apparatus of claim 1, further comprising:
at least one grid detachably covering the aperture.

9. The apparatus of claim 1, further comprising:
at least one outer grid;
at least one inner grid disposed between the outer grid and the chamber; and
a power supply configured to bias the outer grid relative to the inner grid.

10. The apparatus of claim 1, further comprising:
a reactive gas supplier; and
a gas switch switchable between a fluid connection of the reactive gas supplier with the chamber and a fluid connection of the etch gas supplier with the chamber.

11. The apparatus of claim 1, further comprising:
a cleaning gas supplier; and
a gas switch switchable between a fluid connection of the cleaning gas supplier with the chamber and a fluid connection of the etch gas supplier with the chamber.

12. An apparatus for treating a wafer, the apparatus comprising:
a platen;
a chamber having at least one aperture at least partially facing to the platen;
an etch gas supplier fluidly connected to the chamber;
at least one rotating mechanism coupled with the platen for allowing the platen to have at least one first degree of rotational freedom; and
at least one linear motion mechanism coupled with the platen for allowing the platen to have at least one third degree of freedom to move linearly relative to the aperture of the chamber in a direction substantially perpendicular to a normal of the platen.

13. The apparatus of claim 12, further comprising:
a reactive gas supplier;
a gas switch switchable between a fluid connection of the reactive gas supplier with the chamber and a fluid connection of the etch gas supplier with the chamber;
a radio frequency generator coupled with the chamber; and
a controller configured to turn off the radio frequency generator when the gas switch is switched to the fluid connection of the reactive gas supplier with the chamber.

14. The apparatus of claim 12, further comprising:
a reactive gas supplier;
a gas switch switchable between a fluid connection of the reactive gas supplier with the chamber and a fluid connection of the etch gas supplier with the chamber;
a radio frequency generator coupled with the chamber; and
a controller configured to turn on the radio frequency generator when the gas switch is switched to the fluid connection of the etch gas supplier with the chamber.

15-20. (canceled)

21. An apparatus for treating a wafer, the apparatus comprising:
a platen;
a chamber having at least one aperture at least partially facing to the platen;
an etch gas supplier fluidly connected to the chamber; and
at least one linear motion mechanism coupled with the platen for allowing the platen to have at least one first degree of freedom to move linearly relative to the aperture of the chamber in a direction substantially perpendicular to a normal of the platen.

22. (canceled)

23. The apparatus of claim 21, further comprising:
at least one radio frequency generator coupled with the chamber.

24. The apparatus of claim 21, further comprising:
a reactive gas supplier;
a gas switch switchable between a fluid connection of the reactive gas supplier with the chamber and a fluid connection of the etch gas supplier with the chamber;
a radio frequency generator coupled with the chamber; and
a controller configured to turn off the radio frequency generator when the gas switch is switched to the fluid connection of the reactive gas supplier with the chamber.

25. The apparatus of claim 21, further comprising:
a reactive gas supplier;
a gas switch switchable between a fluid connection of the reactive gas supplier with the chamber and a fluid connection of the etch gas supplier with the chamber;
a radio frequency generator coupled with the chamber; and
a controller configured to turn on the radio frequency generator when the gas switch is switched to the fluid connection of the etch gas supplier with the chamber.

26. The apparatus of claim 21, further comprising:
a cleaning gas supplier; and
a gas switch switchable between a fluid connection of the cleaning gas supplier with the chamber and a fluid connection of the etch gas supplier with the chamber.

27. The apparatus of claim 12, further comprising:
at least a pair of magnets with opposite poles coupled with the chamber, the aperture being substantially located between the pair of magnets.

28. The apparatus of claim 12, further comprising:
at least one grid at least partially covering the aperture; and
a power supply configured to bias the grid relative to the chamber.
